(19) United States
(12) Patent Application Publication
(10) Pub. No.: US 2004/0188860 A1
(43) Pub. Date: Sep. 30, 2004

(54) Chip scale package and method for marking the same

(76) Inventors: Yu Pen Tsai, Kaohsiung (TW); Kuo Pin Yang, Kaohsiung (TW); Wu Chung Chiang, Kaohsiung (TW)

Correspondence Address: LOWE HAUPTMAN GILMAN & BERNER, LLP, Suite 310, 1700 Diagonal Road, Alexandria, VA, 22314, US

(21) Appl. No.: 10/804,146

(22) Filed: Mar. 19, 2004

(30) Foreign Application Priority Data
Mar. 26, 2003 (TW) 092107039

(51) Int. Cl. H01L 21/44

(52) U.S. Cl. 257/784

(57) ABSTRACT

A chip scale package includes a plurality of terminals for making external electrical connections and a chip. The chip has a plurality of bonding pads on an active surface thereof, and the bonding pads of the chip are electrically connected to the terminals. The backside surface of the chip is exposed from a surface of the package. The present invention is characterized by having an ink mark on the backside surface of the chip. The present invention further provides a method for making the chip scale package at the wafer level.

### BACKGROUND OF THE INVENTION

1. Field of the Invention

The present invention relates to a marked chip scale package and a method for marking wafer-level chip scale packages.

2. Description of Prior Art

As electronic devices have become smaller and thinner, the velocity and the complexity of IC chip become higher. Accordingly, a need has arisen for higher packaging efficiency. Demand for miniaturization is the primary catalyst driving the usage of advanced packages such as chip scale packages (hereinafter referred to as “CSP”) and flip chips. Both of them greatly reduce the amount of board real estate required when compared to the alternative ball grid array (hereinafter referred to as “BGA”) and thin small outline package (hereinafter referred to as “TSOP”). Typically, the size of a CSP is substantially equal to or slightly larger than the chip (the maximum size of a CSP is 20 percent larger than the chip itself). Another advantage of CSP is that the package facilitates test and burn-in before assembly as an alternative to known good die (KGD) testing. In addition, CSP can combine many of the benefits of surface mount technology (SMT), such as standardization and reworkability, with the benefits of flip chip technology, such as low inductance, high I/O count, and direct thermal path. However, CSP has at least one disadvantage compared to conventional BGA and TSOP, namely, high cost per unit. However, this problem could be eliminated if CSPs could be mass produced more easily. Therefore, the semiconductor packaging industry has tried to develop packaging techniques at the wafer-level for mass production of CSPs, as illustrated in U.S. Pat. No. 5,977,624 and U.S. Pat. No. 6,004,867. The wafer-level packaging technology generally includes directly attaching a substrate to an active surface of a wafer, wherein the semiconductor wafer is not diced into individual chips yet. The substrate includes a plurality of units corresponding to the chips on the wafer, and the dimensions thereof are substantially the same as the wafer. According to the wafer-level semiconductor packages disclosed in the aforementioned US Patents, each chip of the wafer is encapsulated before die dicing and the backside surface of the wafer is exposed from the encapsulant. After encapsulation, encapsulated wafer is diced into individual semiconductor packages.

In order to satisfy the need for corporate identity, product differentiation, product type identification and establishing reputation, it is necessary to mark each semiconductor package. Conventional semiconductor packages generally have encapsulant covering and protecting the chips therein. Therefore, the above-mentioned information can be directly marked on the encapsulant. It should be noticed that marking of the chip scale packages manufactured by the above-mentioned wafer-level package technology are typically accomplished by laser marking the backside surface of the wafer which is exposed from the encapsulant. However, laser marking is a destructive technique and it is not easy to control the marking depth thereof. If the marking depth is too shallow, the laser mark may become unrecognizable, and if the marking depth is too deep, the laser mark may damage the internal circuits of the wafer. In addition, fragments and burrs are inevitably formed at the marking sites during the laser marking. However, when the semiconductor chip packages are used in electronic products (e.g. hard disks), the fragments and burrs may cause malfunctions of the electronic products.

### SUMMARY OF THE INVENTION

It is an objective of the present invention to provide a chip scale package having a distinct mark created on a marked surface without any destructive changes.

It is another objective of the present invention to provide a method for marking chip scale packages at the wafer level wherein semi-finished chip scale packages on a wafer are marked in a non-destructive way thereby overcoming or at least reducing the problems created during laser marking.

The chip scale package according to one embodiment of the present invention includes a plurality of terminals for making external electrical connections and a chip. The chip has a plurality of bonding pads on an active surface thereof. The bonding pads are electrically connected to the terminals. A backside surface of the chip is exposed from a surface of the chip scale package. The present invention is characterized in that the backside surface of the chip has a mark and the mark is an ink mark.

The present invention further provides a method for marking chip scale packages at the wafer level. First, a positioning step is performed to determine the position of a plurality of semi-finished chip scale packages formed on a wafer. The semi-finished chip scale package includes a plurality of terminals for making external electrical connections and a die having a plurality of bonding pads on an active surface thereof. The bonding pads are electrically connected to the terminals wherein a backside surface of the die is exposed from a surface of the semi-finished chip scale package.

Then, the exposed backside surface of the die is marked by ink printing. Next, the ink on each die is cured. At last, the wafer is diced to obtain a plurality of chip scale packages wherein each package is separated from other packages.

According to one embodiment of the present invention, defective ink marks formed on the dice can be removed after the printing step and before the curing step thereby carrying out non-destructive rework.

It is preferred that the positioning device used in the positioning step and the printing device used in the printing step are positioned on two opposing sides of the wafer, and the printing step is performed by coaxially aligning the printing device with the positioning device. In addition, the semi-finished chip scale packages are separated by a plurality of dicing streets, and the positioning step is performed by finding the dicing streets with a charge coupled device (CCD).

The marking method of the present invention utilizes ink printing to directly mark the backside surface of the wafer/chip in a non-destructive way. Therefore, the present invention can overcome or at least reduce the problems found in conventional laser marking techniques. In addition, the ink marks on the backside surface of the wafer/chip can be removed easily. Therefore, another advantage of the present invention is that defective marks can be repaired in a non-destructive way thereby allowing non-destructive rework.

Other objects, aspects and advantages will become apparent from the following description of embodiments with reference to the accompanying drawings.

### BRIEF DESCRIPTION OF DRAWINGS

FIG. 1a is a cross-section view of a chip scale package according to one embodiment of the present invention;

FIG. 1b is a bottom plan view of the chip scale package of FIG. 1a; and

FIG. 2 illustrates a main step of marking semi-finished chip scale packages on a wafer in a perspective view according to another embodiment of the present invention.

### DETAILED DESCRIPTION OF THE PREFERRED EMBODIMENTS

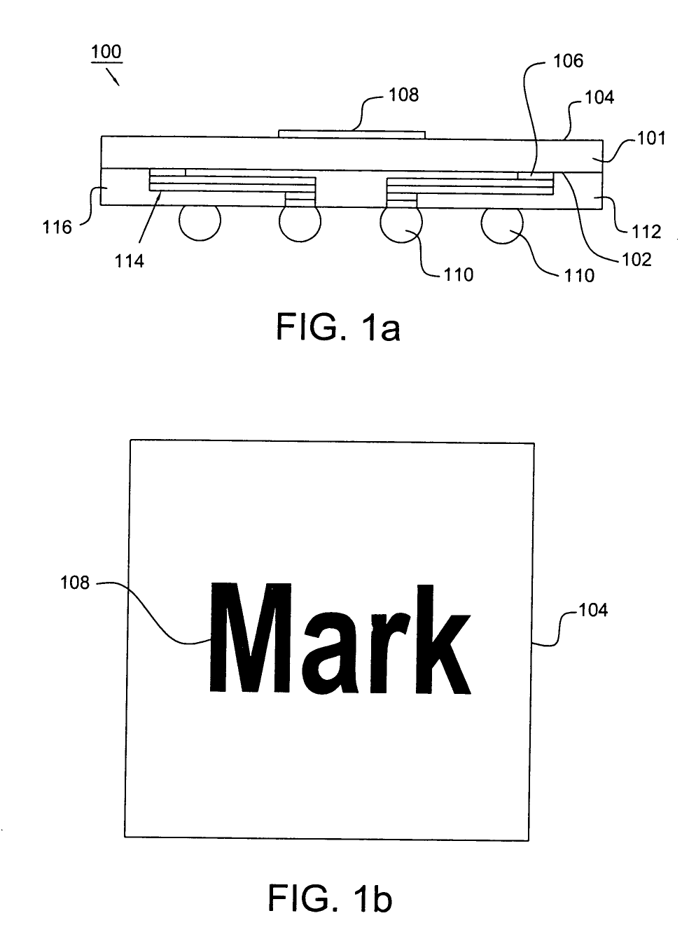

Referring to the FIG. 1a, the present invention provides a chip scale package 100 includes a plurality of terminals such as solder balls 110 for making external electrical connections and a chip 101. The chip 101 has a plurality of bonding pads 106 formed on an active surface 102 thereof. The bonding pads 106 are electrically connected to the solder balls 110. According to one embodiment of the present invention, the chip scale package 100 has a redistribution layer 112 including a dielectric layer 116 and multi-layer metal conductive traces 114. The bonding pads 106 of the chip 101 can be electrically connected to the solder balls 110 through the conductive traces 114 in the redistribution layer 112. A backside surface 104 of the chip 101 is exposed from a surface of the chip scale package 100 and has an ink mark 108 (see FIG. 1b).

The ink mark on the chip can satisfy needs for corporate identity, product differentiation, product type identification and counterfeit protection.

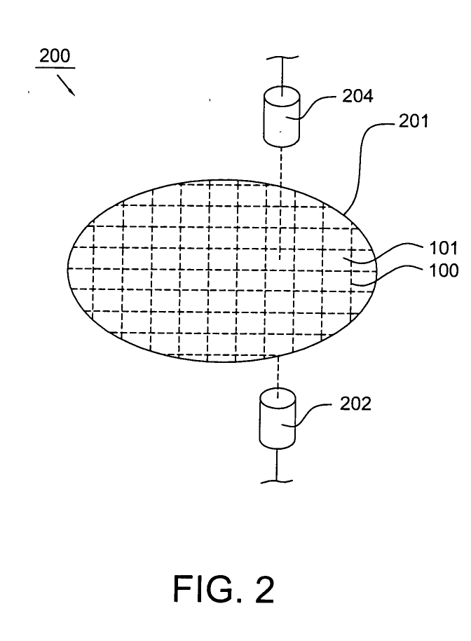

The present invention also provides a method for marking chip scale packages at the wafer level. The FIG. 2 illustrates a wafer 201 includes a plurality of dice 101 and the dice have been packaged into a plurality of semi-finished chip scale packages. Each of the semi-finished chip scale packages is substantially identical to the chip scale package 100 of FIG. 1 with the exceptions that the semi-finished chip scale packages are formed on the wafer and not diced yet. The semi-finished chip scale packages are separated from each other by a plurality of dicing streets. First, a positioning step is performed to determine the position of the packaged dice 101 on the wafer 201. Specifically, a positioning device 202 such as a charge coupled device (CCD) is used to find the dicing streets thereby determining the coordinates of the packaged dice 101 on the wafer 201. In the positioning step, the packaged dice 101 may be positioned one at a time. Alternatively, all of the packaged dice 101 may be positioned simultaneously.

Then, a printing head of a printing device 204 is moved to be aligned with the backside surface of a target die in accordance with the coordinates of the target die and print an ink mark on the backside surface of the target die. At last, the wafer 201 is diced to obtain a plurality of chip scale packages 100 wherein each package is separated from other packages. As shown in FIG. 2, the positioning device 202 and the printing device 204 may be disposed on two opposing sides of the wafer 201 such that the positioning step and the printing step can be performed synchronously by coaxially aligning the printing device with the positioning device.

Furthermore, in the method according to another embodiment of the present invention, the printing step can be performed by printing the backside surfaces of all of the dice in one action by a printing device in accordance with the coordinates of all the packaged dice 101 obtained in the positioning step.

The marking method of the present invention utilizes ink printing to directly mark the backside surface of the wafer/chip in a non-destructive way thereby overcoming or at least reducing the problems found in conventional laser marking techniques. In addition, no fragments or burrs will be created during the marking process provided by the present invention thereby obviating the contamination problem found in conventional laser marking techniques. Besides, the ink marks on the backside surface of the wafer/chip can be removed easily before they are cured. Therefore, another advantage of the present invention is that defective marks can be repaired in a non-destructive way thereby allowing non-destructive rework

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A chip scale package comprising:
a plurality of terminals for making external electrical connections;
a chip having a plurality of bonding pads on an active surface thereof, the bonding pads electrically connected to the terminals, wherein a backside surface of the chip is exposed from a surface of the chip scale package; and
an ink mark formed on the backside surface of the chip.

2. A method for marking wafer-level chip scale packages, the method comprising the following steps:
providing a wafer having a plurality of dice formed thereon, wherein the dice have been packaged into a plurality of semi-finished chip scale packages, wherein the semi-finished chip scale packages comprises a plurality of terminals for making external electrical connections, each die has a plurality of bonding pads on an active surface thereof, the bonding pads are electrically connected to the terminals, and a backside surface of each die is exposed from a surface of the semi-finished chip scale packages;
positioning the semi-finished chip scale packages formed on the wafer;
printing ink marks on the exposed backside surface of the dice;
curing the ink marks on the dice; and
dicing the wafer to obtain a plurality of chip scale packages wherein each package is separated from other packages.

3. The method as claimed in claim 2, further comprising a step of removing defective ink marks after the printing step and before the curing step.

4. The method as claimed in claim 2, wherein the positioning step is performed by a positioning device and the printing step is performed by a printing device, the positioning device and the printing device are positioned on two opposing sides of the wafer, and the printing step is performed by coaxially aligning the printing device with the positioning device.

5. The method as claimed in claim 2, wherein the wafer has a plurality of dicing streets between the semi-finished chip scale packages, and the position step is performed by finding the dicing street with a charge coupled device (CCD).

6. The method as claimed in claim 5, wherein the positioning step is performed by a positioning device and the printing step is performed by a printing device, the positioning device and the printing device are positioned on two opposing sides of the wafer, and the printing step is performed by coaxially aligning the printing device with the positioning device.

7. A semiconductor wafer comprising a plurality of dice wherein each of dice has a plurality of bonding pads on an active surface thereof and an ink mark on a backside surface thereof.

8. A semiconductor die comprising a plurality of bonding pads on an active surface thereof and an ink mark on a backside surface thereof.
